(19) United States
(12) Patent Application Publication
(10) Pub. No.: US 2010/0013521 A1
(43) Pub. Date: Jan. 21, 2010

(54) SYNTHESIZER FOR DOHERTY AMPLIFIER

(75) Inventors: Atsuo Mizuma, Nagano-Prefecture (JP); Masashi Aiba, Nagano-Prefecture (JP)

Correspondence Address: BURR & BROWN, PO BOX 7068, SYRACUSE, NY, 13261-7068, US

(73) Assignee: Soshin Electric Co., Ltd, Saku-City (JP)

(21) Appl. No.: 12/527,589

(22) PCT Filed: Mar. 28, 2008
(86) PCT No.: PCT/JP2008/056152

§ 371 Date: Aug. 18, 2009

(30) Foreign Application Priority Data
Mar. 29, 2007 (JP) 2007-087650

(51) Int. Cl. H03B 21/00

(52) U.S. Cl. 327/105

(57) ABSTRACT

A synthesizer is constructed by constituting a first λ/4 line of a first strip line and by constituting a second λ/4 line of a second strip line, so that it is formed into a chip shape (or a chip part) in a dielectric substrate. A first shield electrode is formed on the upper face of the dielectric substrate, and a second shield electrode is formed on the lower face of the dielectric substrate, so that the first λ/4 line and the second λ/4 line are formed between the first shield electrode and the second shield electrode.

### TECHNICAL FIELD

The present invention relates to a synthesizer for a Doherty amplifier, to be connected to the output stage of a Doherty amplifier, for combining an output signal from a carrier amplifier and an output signal from a peak amplifier.

### BACKGROUND ART

Generally, Doherty amplifiers are known as high-frequency amplifying circuits for use in base stations of wireless communication systems such as cellular telephone systems or the like (see Patent documents 1 through 4).

As shown in FIG. 5, a Doherty amplifier 100 comprises a carrier amplifier 102 made up of FETs and a peak amplifier 104 made up of FETs. The carrier amplifier 102 is an amplifier biased into class A or AB or B, and the peak amplifier 104 is an amplifier with a reduced current, i.e., biased into class C.

A high-frequency signal input from an input terminal 106 is divided into two signals. One of the signals is input to the carrier amplifier 102. The other signal is shifted 90 degrees out of phase by a λ/4 line 108, and then input to the peak amplifier 104. The carrier amplifier 102 has an output terminal connected to a first λ/4 line L1. The output signal from the carrier amplifier 102 passes through the first λ/4 line L1 to a combining point 110 where it is combined with the output signal from the peak amplifier 104. The Doherty amplifier 100 has an output terminal 112 connected to a load resistor 114. A second λ/4 line L2 is connected between the combining point 110 and the output terminal 112 for impedance conversion to match the load resistor 114.

When the high-frequency signal has a low input level, since the peak amplifier 104 is biased into class C, it is in an off-state and does not consume electric power. The input signal is amplified by the carrier amplifier 102 that is biased into class A or AB or B. Since the DC power consumption of the peak amplifier 104 is nil or sufficiently small, the Doherty amplifier 100 is highly efficient as a whole.

When the input level of the high-frequency signal becomes equal to or higher than a certain value, the carrier amplifier 102 starts to be saturated. The peak amplifier 104 is turned on and operates to make up for a gain reduction caused by the saturated carrier amplifier 102.

As described above, the Doherty amplifier 100 can operate highly efficiently because the peak amplifier 104 operates only when the level of a signal having a large average to peak power ratio is high.

The efficiency of the Doherty amplifier 100 is further increased by the first λ/4 line L1 that is connected to the output terminal of the carrier amplifier 102 to change the apparent load impedance of the carrier amplifier 102.

Specifically, the output impedance as seen from the carrier amplifier 102 is regarded as 2Z0 due to the first λ/4 line L1 connected to the carrier amplifier 102 and the second λ/4 line L2 connected to the output terminal 112. At this time, the output power of the Doherty amplifier 100 is expressed as V0²/2Z0 where V0 represents the output voltage of the carrier amplifier 102.

Normally, the FET has its operation efficiency determined depending on the output voltage thereof, such that the operation efficiency becomes better as the output voltage is higher. When the input level of the Doherty amplifier 100 is low, the Doherty amplifier 100 is as efficient as the FET connected to a load impedance Z0, with one-half of the output power of the FET.

As the input level gradually increases, the peak amplifier 104 starts to operate progressively. In this state, the peak amplifier 104 supplies output power and at the same time the carrier amplifier 102 has its load impedance reduced from 2Z0 to Z0. Therefore, the carrier amplifier 102 increases its output power while remaining highly efficient.

When the input level is sufficiently high, since both the carrier amplifier 102 and the peak amplifier 104 are in operation, their output impedances are matched to Z0, and the output power of the Doherty amplifier 100 is expressed as 2×V0²/Z0.

As described above, the Doherty amplifier 100 is highly efficient at an operating point where the input level is low and a so-called back-off is large, as compared with conventional class A and class AB amplifiers.

Patent document 1: Japanese Laid-Open Patent Publication No. 2004-173231
Patent document 2: Japanese Laid-Open Patent Publication No. 2006-173722
Patent document 3: Japanese Laid-Open Patent Publication No. 2006-345341
Patent document 4: Japanese Laid-Open Patent Publication No. 2007-19570

### DISCLOSURE OF THE INVENTION

As shown in FIG. 6, the conventional Doherty amplifier 100 has a printed wiring board 116 with the carrier amplifier 102 and the peak amplifier 104 being mounted thereon and the first λ/4 line L1 and the second λ/4 line L2 being disposed as microstrip lines thereon.

The printed wiring board 116 comprises a resin-based board including a base impregnated with an insulative resin and a circuit (pattern) disposed thereon which is made of an electric conductor such as copper foil or the like. The first λ/4 line L1 and the second λ/4 line L2 are made of an electric conductor and disposed directly on the resin-based board.

Since the first λ/4 line L1 and the second λ/4 line L2 of an electric conductor are simply constructed on the printed wiring board 116, there is no consideration for reducing the length of the first λ/4 line L1 and the second λ/4 line L2, and the printed wiring board 116 needs to have a large area to be occupied by the first λ/4 line L1 and the second λ/4 line L2. The first λ/4 line L1 and the second λ/4 line L2 are susceptible to electromagnetic waves leaking from other transmission paths. When the first λ/4 line L1 and the second λ/4 line L2 are formed, they need to match the inherence impedances of the semiconductor devices (FETs, etc.) of the carrier amplifier 102 and the peak amplifier 104. Therefore, it is time-consuming to produce patterns for the first λ/4 line L1 and the second λ/4 line L2. Once the first λ/4 line L1 and the second λ/4 line L2 have been formed, they cannot be replaced. Accordingly, the semiconductor devices cannot be changed to semiconductor devices of other types (e.g., those with different frequency bands to be used), but the entire printed wiring board has to be replaced to change the semiconductor devices.

The present invention has been made in view of the above problems. It is an object of the present invention to provide a synthesizer for use with a Doherty amplifier, which will solve the above problems caused by directly forming a first λ/4 line and a second λ/4 line on a printed wiring board, and which makes it possible to reduce the size of the Doherty amplifier and improve the characteristics of the Doherty amplifier.

Another object of the present invention is to provide a synthesizer for use with a Doherty amplifier in which the synthesizer has only to be replaced, while a printed wiring board does not need to be replaced, but can be shared, when semiconductor devices making up a carrier amplifier and a peak amplifier are changed to semiconductor devices of other types (e.g., those with different frequency bands to be used).

According to the present invention, a synthesizer for a Doherty amplifier, to be connected to the output stage of a Doherty amplifier, for combining an output signal from a carrier amplifier and an output signal from a peak amplifier, comprises a first λ/4 line connected between a combining point for combining the output signal from the carrier amplifier and the output signal from the peak amplifier and the carrier amplifier, and a second λ/4 line connected between the combining point and an output terminal, wherein each of the first λ/4 line and the second λ/4 line comprises a stripline, and the first λ/4 line and the second λ/4 line are disposed in a dielectric board, providing a chip-like structure (chip component).

Therefore, the area which is occupied by the first λ/4 line and the second λ/4 line on a printed wiring board is greatly reduced to a value which is about one-tenth of the occupied area in the conventional synthesizer. If the dielectric board is made of ceramics, then its temperature characteristics are improved compared with a resin-based board such as a printed wiring board, and its performance are prevented from deteriorating due to temperature changes of the Doherty amplifier itself and the environment around the Doherty amplifier.

The first λ/4 line and the second λ/4 line that match the inherent impedances of the carrier amplifier and the peak amplifier can be supplied as a chip component. Therefore, the manufacturing process can greatly be simplified. Inasmuch as the first λ/4 line and the second λ/4 line are disposed in the dielectric board, the synthesizer has only to be mounted on the printed wiring board, and impedance conversion can be achieved essentially as designed. If the dielectric board is made of a dielectric material having a high Q value, then the insertion loss is reduced, and the electric power can be saved. Thus, the Doherty amplifier which is able to deal with environmental problems is obtained.

Even when semiconductor devices, for example, making up the carrier amplifier and the peak amplifier are changed to semiconductor devices of other types (e.g., those with different frequency bands to be used), the synthesizer has only to be replaced, while the printed wiring board itself does not need to be replaced, but can be shared. As the printed wiring board does not need to be replaced, the manufacturing and designing costs can be reduced, and environmental problems are dealt with from a material viewpoint.

According to the present invention, a first shield electrode may be disposed on an upper portion of the dielectric board, a second shield electrode may be disposed on a lower portion of the dielectric board, and the first λ/4 line and the second λ/4 line may be disposed in the dielectric board between the first shield electrode and the second shield electrode. In this case, the first λ/4 line and the second λ/4 line are less susceptible to electromagnetic waves leaking from other transmission paths, and have improved characteristics.

Preferably, an inner-layer shield electrode may be disposed in the dielectric board, either one of the first λ/4 line and the second λ/4 line may be disposed between the first shield electrode and the inner-layer shield electrode, and one of the first λ/4 line and the second λ/4 line which is different from the one of the first λ/4 line and the second λ/4 line that is disposed between the first shield electrode and the inner-layer shield electrode may be disposed between the second shield electrode and the inner-layer shield electrode. In this case, any interference between the first λ/4 line and the second λ/4 line is reduced. The distances between the lines and the shield electrodes can individually be established, allowing the synthesizer to be designed with ease.

As described above, the synthesizer for use with the Doherty amplifier according to the present invention offers the following advantages:

(1) The area which is occupied by the first λ/4 line and the second λ/4 line on the printed wiring board is greatly reduced.

(2) If the dielectric board is made of ceramics, then its temperature characteristics are improved compared with a resin-based board such as a printed wiring board.

(3) The first λ/4 line and the second λ/4 line that match the inherent impedances of the carrier amplifier and the peak amplifier can be supplied as a chip component.

(4) If the dielectric board is made of a dielectric material having a high Q value, then the insertion loss is reduced, and the electric power can be saved.

(5) The first λ/4 line and the second λ/4 line are less susceptible to electromagnetic waves leaking from other transmission paths.

(6) Any interference between the first λ/4 line and the second λ/4 line is reduced.

(7) Even when semiconductor devices, for example, making up the amplifiers are changed to semiconductor devices of other types, the synthesizer has only to be replaced, while the printed wiring board can be shared.

(8) As the printed wiring board does not need to be replaced, the manufacturing and designing costs can be reduced, and environmental problems are dealt with from a material viewpoint.

### BRIEF DESCRIPTION OF THE DRAWINGS

FIG. 1 is a perspective view, partly omitted from illustration, of an assembly including a synthesizer according to an embodiment of the present invention which is mounted on a printed wiring board;

FIG. 2 is a perspective view of the synthesizer according to the embodiment;

FIG. 3 is an exploded perspective view of the synthesizer according to the embodiment;

FIG. 4 is a perspective view of a synthesizer according to a modification;

FIG. 5 is a circuit diagram showing a general Doherty amplifier; and

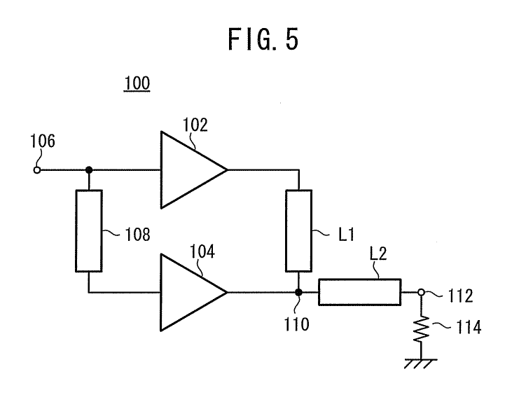

FIG. 6 is a perspective view of a conventional Doherty amplifier which is mounted on a printed wiring board.

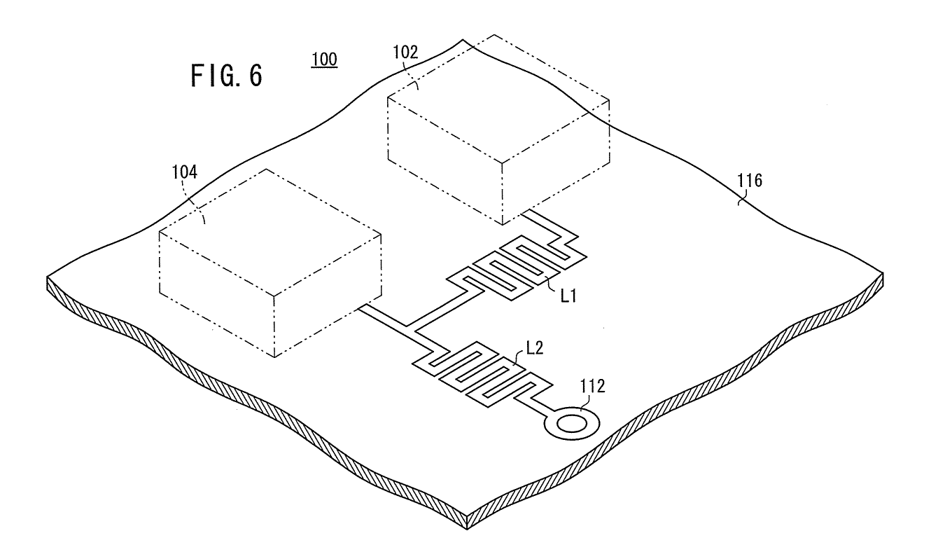

### BEST MODE FOR CARRYING OUT THE INVENTION

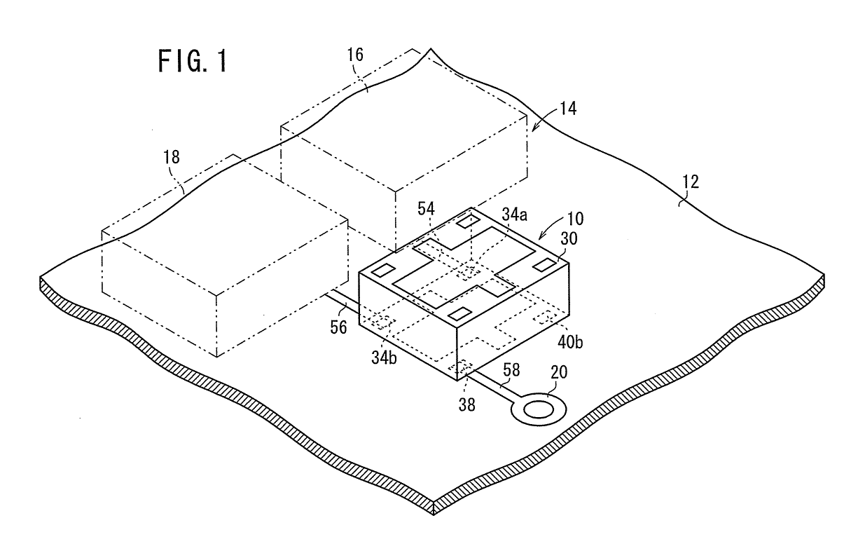

Synthesizers for use with a Doherty amplifier according to embodiments of the present invention will be described below with reference to FIGS. 1 through 4.

As shown in FIG. 1, a synthesizer for use with a Doherty amplifier (hereinafter referred to as a synthesizer 10) according to an embodiment of the present invention is constructed as a chip-like component (chip component) disposed between a carrier amplifier 16 and a peak amplifier 18 and an output terminal 20 of a Doherty amplifier 14 which is mounted on a printed wiring board 12.

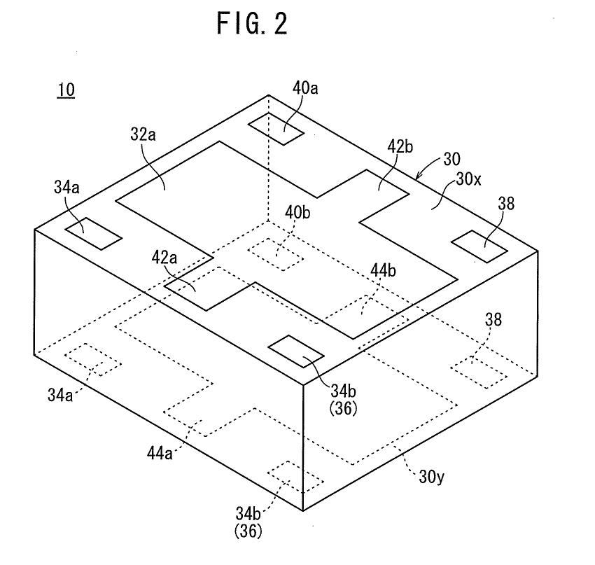

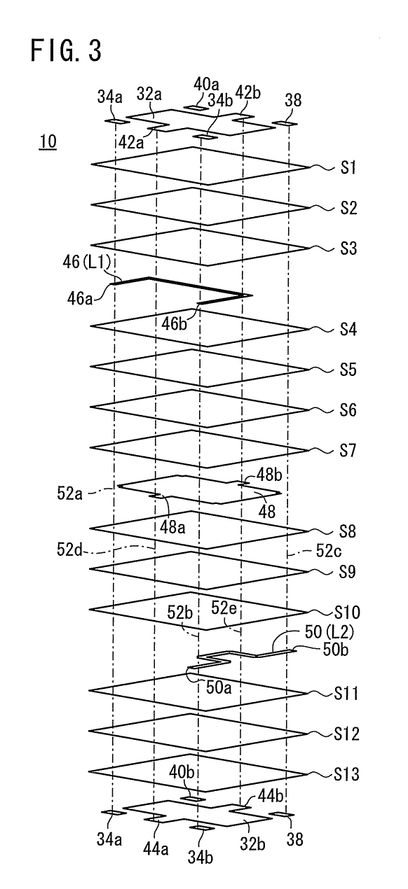

Specifically, as shown in FIG. 2, the synthesizer includes a dielectric board 30 comprising a plurality of dielectric layers (dielectric layers S1 through S13, see FIG. 3) that are stacked and sintered into a unitary body. The dielectric board 30 has, on an upper surface 30x thereof, a first shield electrode 32a, a first input terminal 34a, a second input terminal 34b (a terminal serving as a combining point 36), an output terminal 38, and a first NC terminal 40a (nothing connected thereto), and also has, on a lower surface 30y thereof, a second shield electrode 32b, a first input terminal 34a, a second input terminal 34b (a terminal serving as a combining point 36), an output terminal 38, and a second NC terminal 40b.

The carrier amplifier 16 has an output connected to the first input terminals 34a, and the peak amplifier 18 has an output connected to the second input terminals 34b. The output terminal 20 of the Doherty amplifier 14 or a load is connected to the output terminals 38.

The first shield electrode 32a has a first wing 42a positioned between the first input terminal 34a and the second input terminal 34b on the upper surface 30x of the dielectric board 30. The first shield electrode 32a also has a second wing 42b positioned between the output terminal 38 and the first NC terminal 40a on the upper surface 30x.

Similarly, the second shield electrode 32b has a first wing 44a positioned between the first input terminal 34a and the second input terminal 34b on the lower surface 30y of the dielectric board 30. The second shield electrode 32b also has a second wing 44b positioned between the output terminal 38 and the second NC terminal 40b on the lower surface 30y.

As shown in FIG. 3, the dielectric board 30 is constructed of first through thirteenth dielectric layers S1 through S13 which are successively stacked in downward order. The first through thirteenth dielectric layers S1 through S13 comprise one or plural layers.

A first stripline 46 which serves as a first λ/4 line L1 is disposed on a principal surface of the fourth dielectric layer S4. An inner-layer shield electrode 48 is disposed on a principal surface of the eighth dielectric layer S8. A second stripline 50 which serves as a second λ/4 line L2 is disposed on a principal surface of the eleventh dielectric layer S11. Alternatively, a second stripline 50 which serves as a second λ/4 line L2 may be disposed on a principal surface of the fourth dielectric layer S4, and a first stripline 46 which serves as a first λ/4 line L1 may be disposed on a principal surface of the eleventh dielectric layer S11. The distances between the first stripline 46 and the second stripline 50, and the first shield electrode 32a, the second shield electrode 32b, or the inner-layer shield electrode 48 are not limited to those shown in FIG. 3, but may be designed appropriately depending on the carrier amplifier 16 and the peak amplifier 18 that are used. Although not shown, the shapes, thicknesses, and lengths of the striplines are designed depending on the carrier amplifier 16 and the peak amplifier 18 that are used, and are not limited to those shown in FIG. 3. Although not shown, the inner-layer shield electrode 48 may be dispensed with. Although not shown, the dielectric layers may be employed in any number of tiers (any number of layers) depending on the carrier amplifier 16 and the peak amplifier 18 that are used, and are not limited to those shown in FIG. 3.

The first stripline 46 has an end 46a electrically connected to the first input terminal 34a on the upper surface and the first input terminal 34a on the lower surface by a first via hole 52a. The first stripline 46 has another end 46b electrically connected to the second input terminal 34b on the upper surface, the second input terminal 34b on the lower surface, and an end 50a of the second stripline 50 by a second via hole 52b. The second stripline 50 has another end 50b electrically connected to the output terminal 38 on the upper surface and the output terminal 38 on the lower surface by a third via hole 52c. Likewise, the inner-layer shield electrode 48 has a first wing 48a electrically connected to the first wing 42a of the first shield electrode 32a and the first wing 44a of the second shield electrode 32b by a fourth via hole 52d. The inner-layer shield electrode 48 has a second wing 48b electrically connected to the second wing 42b of the first shield electrode 32a and the second wing 44b of the second shield electrode 32b by a fifth via hole 52e.

In this manner, the synthesizer 10 is constructed as a chip component which has a first λ/4 line L1 connected between the combining point 36 (the second input terminal 34b) and the carrier amplifier 16 and a second λ/4 line L2 connected between the combining point 36 and the output terminal 38.

The synthesizer 10 can be surface-mounted on the printed wiring board 12. As shown in FIG. 1, for example, an end (pad) of a wiring pattern 54 which extends from the output terminal of the carrier amplifier 16 and the first input terminal 34a of the synthesizer 10 are positioned in alignment with each other. An end (pad) of a wiring pattern 56 which extends from the output terminal of the peak amplifier 18 and the second input terminal 34b of the synthesizer 10 are positioned in alignment with each other. An end (pad) of a wiring pattern 58 which extends from the output terminal 20 and the output terminal 38 of the synthesizer 10 are positioned in alignment with each other. Then, the ends of the wiring patterns and the terminals that are aligned with each other are soldered, thereby surface-mounting the synthesizer 10 on the printed wiring board 12.

With the synthesizer 10 according to the present embodiment, the first λ/4 line L1 is constructed as the first stripline 46, and the second λ/4 line L2 is constructed as the second stripline 50. The first and second striplines are formed in the dielectric board 30, providing the chip-like component (chip component).

Therefore, the area which is occupied by the first λ/4 line L1 and the second λ/4 line L2 on the printed wiring board 12 is greatly reduced to a value which is about one-tenth of the occupied area in the conventional synthesizer. If the dielectric board 30 is made of ceramics, then its temperature characteristics are improved compared with a resin-based board such as the printed wiring board 12, and its performance are prevented from deteriorating due to temperature changes of the Doherty amplifier 14 itself and the environment around the Doherty amplifier 14.

The first λ/4 line L1 and the second λ/4 line L2 that match the inherent impedances of the carrier amplifier 16 and the peak amplifier 18 can be supplied as a chip component. Therefore, the manufacturing process can greatly be simplified. Inasmuch as the first λ/4 line L1 and the second λ/4 line L2 are disposed in the dielectric board 30, the synthesizer 10 has only to be mounted on the printed wiring board 12, and impedance conversion can be achieved essentially as designed. If the dielectric board 30 is made of a dielectric material having a high Q value, then the insertion loss is reduced, and the electric power can be saved. Thus, the Doherty amplifier 14 which is able to deal with environmental problems is obtained.

Since the first shield electrode 32a is disposed on the upper surface 30x of the dielectric board 30, the second shield electrode 32b is disposed on the lower surface 30y of the dielectric board 30, and the first λ/4 line L1 and the second λ/4 line L2 are disposed between the first shield electrode 32a and the second shield electrode 32b, the first λ/4 line L1 and the second λ/4 line L2 are less susceptible to electromagnetic waves leaking from other transmission paths, and have improved characteristics.

Even when semiconductor devices, for example, making up the carrier amplifier 16 and the peak amplifier 18 are changed to semiconductor devices of other types (e.g., those with different frequency bands to be used), the synthesizer has only to be replaced, while the printed wiring board 12 itself does not need to be replaced, but can be shared. As the printed wiring board 12 does not need to be replaced, the manufacturing and designing costs can be reduced, and environmental problems are dealt with from a material viewpoint.

According to the present embodiment, the inner-layer shield electrode 48 is disposed centrally in the dielectric board 30 in its heightwise direction, the first stripline 46 serving as the first λ/4 line L1 is disposed between the first shield electrode 32a and the inner-layer shield electrode 48, and the second stripline 50 serving as the second λ/4 line L2 is disposed between the second shield electrode 32b and the inner-layer shield electrode 48. Therefore, any interference between the first λ/4 line L1 and the second λ/4 line L2 is reduced. The distances between the lines and the shield electrodes can individually be established, allowing the synthesizer 10 to be designed with ease.

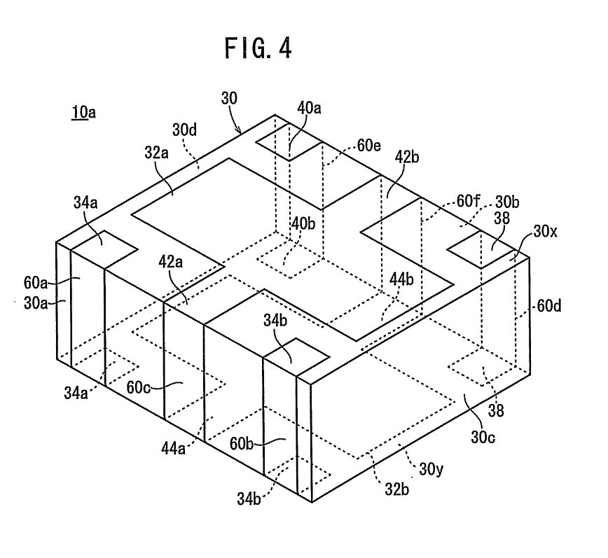

A modification of the synthesizer 10 will be described below with reference to FIG. 4.

As shown in FIG. 4, a synthesizer 10a according to a modification is different in that a first side terminal 60a connected to the first input terminals 34a, a second side terminal 60b connected to the second input terminals 34b, and a third side terminal 60c interconnecting the first wing 42a of the first shield electrode 32a and the first wing 44a of the second shield electrode 32b are disposed on a first side 30a of the dielectric board 30, and a fourth side terminal 60d connected to the output terminals 38, a fifth side terminal 60e interconnecting the first NC terminal 40a and the second NC terminal 40b, and a sixth side terminal 60f interconnecting the second wing 42b of the first shield electrode 32a and the second wing 44b of the second shield electrode 32b are disposed on a second side 30b of the dielectric board 30 (a side opposite to the first side 30a).

Although not shown in FIG. 4, the end 46a of the first stripline 46 is connected to the first side terminal 60a, the other end 46b of the first stripline 46 and the end 50a of the second stripline 50 are connected to the second side terminal 60b, and the other end 50b of the second stripline 50 is connected to the fourth side terminal 60d. Similarly, the first wing 48a of the inner-layer shield electrode 48 is connected to the third side terminal 60c, and the second wing 48b of the inner-layer shield electrode 48 is connected to the sixth side terminal 60f. Furthermore, although not shown, side terminals may be disposed on a third side 30c and a fourth side 30d of the dielectric board 30. Although not shown, the layout of the terminals is not limited to those of the embodiment and the modification, but is designed depending on the carrier amplifier 16 and the peak amplifier 18 that are used, and is not limited to those shown in FIGS. 2 and 3.

According to the modification, the synthesizer is surface-mounted using the side terminals, and the first through fifth via holes 52a through 52e can be dispensed with.

The synthesizer for a Doherty amplifier according to the present invention is not limited to the above embodiments, but various arrangements can be adopted without departing from the scope of the present invention.

1. A synthesizer for a Doherty, to be connected to the output stage of a Doherty amplifier, for combining an output signal from a carrier amplifier and an output signal from a peak amplifier, comprising:
a first λ/4 line connected between a combining point for combining the output signal from the carrier amplifier and the output signal from the peak amplifier and the carrier amplifier; and
a second λ/4 line connected between the combining point and an output terminal;
wherein each of the first λ/4 line and the second λ/4 line comprises a stripline, and the first λ/4 line and the second λ/4 line are disposed in a dielectric board, providing a chip-like structure.

2. A synthesizer according to claim 1, wherein
a first shield electrode is disposed on an upper portion of the dielectric board;
a second shield electrode is disposed on a lower portion of the dielectric board; and
the first λ/4 line and the second λ/4 line are disposed in the dielectric board between the first shield electrode and the second shield electrode.

3. A synthesizer according to claim 2, wherein
an inner-layer shield electrode is disposed in the dielectric board;
either one of the first λ/4 line and the second λ/4 line is disposed between the first shield electrode and the inner-layer shield electrode; and
one of the first λ/4 line and the second λ/4 line which is different from the one of the first λ/4 line and the second λ/4 line that is disposed between the first shield electrode and the inner-layer shield electrode is disposed between the second shield electrode and the inner-layer shield electrode.
